(19) United States
(12) Patent Application Publication
(10) Pub. No.: US 2026/0271268 A1
(43) Pub. Date: Sep. 10, 2026

(54) SEMICONDUCTOR MEMORY DEVICE

(71) Applicant: Samsung Electronics Co., Ltd., Suwon-si (KR)

(72) Inventors: MoonJung YONG, Suwon-si (KR); JUNGOO KANG, Suwon-si (KR); Taesoon KIM, Suwon-si (KR)

(21) Appl. No.: 19/418,514

(22) Filed: Dec. 12, 2025

(30) Foreign Application Priority Data
Mar. 7, 2025 (KR) 10-2025-0029452

(51) Int. Cl. H10B 12/00

(52) U.S. Cl. CPC H10B 12/315; H10B 12/033

(57) ABSTRACT

A semiconductor memory device includes a first capacitor electrode on a substrate, a second capacitor electrode on the first capacitor electrode, and a capacitor dielectric layer between the first capacitor electrode and the second capacitor electrode. The first capacitor electrode includes a conductive pillar and a first conductive pattern surrounding the conductive pillar. The first conductive pattern includes a first material doped with a second material. The conductive pillar includes the second material doped with the first material. The first material and the second material are different from each other.

### CROSS-REFERENCE TO RELATED APPLICATIONS

This U.S. non-provisional patent application claims priority under 35 U.S.C. §119 to Korean Patent Application No. 10-2025-0029452, filed on Mar. 07, 2025 in the Korean Intellectual Property Office, the entire contents of which are hereby incorporated by reference.

### BACKGROUND

The embodiments of inventive concepts relate to a semiconductor memory device, and more particularly, to a semiconductor memory device with improved electrical characteristics and durability.

Due to small-sized, multifunctional, and/or low-cost characteristics, semiconductor devices are being esteemed as important elements in the electronics industry. The semiconductor devices are classified into a semiconductor memory device for storing data, a semiconductor logic device for processing data, and a hybrid semiconductor device including both memory and logic elements. Due to the recent increasing demand for electronic devices with a fast speed and/or low power consumption, the semiconductor device requires a fast-operating speed and/or a low operating voltage. To satisfy the requirement, it is necessary to increase the integration density of the semiconductor device.

### SUMMARY

The embodiments of inventive concepts relate to a semiconductor memory device with improved electrical characteristics.

The embodiments of inventive concepts relate to a semiconductor memory device with improved durability.

A semiconductor memory device according to some embodiments of the inventive concept may include a cell transistor provided with a substrate; a first capacitor electrode on the substrate, the first capacitor electrode being electrically connected to the cell transistor; a second capacitor electrode on the first capacitor electrode; and a capacitor dielectric layer between the first capacitor electrode and the second capacitor electrode. The first capacitor electrode includes a conductive pillar and a first conductive pattern surrounding the conductive pillar. The first conductive pattern comprises a first material including a first element and doped with a second element, the first element being different from the second element, the conductive pillar comprises a second material including the first element and doped with the second element, and the first material and the second material are different from each other.

A semiconductor memory device according to some embodiments of inventive concept may include a word line crossing an active pattern, a bit line crossing the word line and on the word line, a landing pad spaced apart from the word line and the bit line, and a data storage pattern connected to the landing pad, wherein the data storage pattern includes a bottom electrode, a top electrode, and a dielectric layer therebetween, and the bottom electrode includes a conductive pillar extending in a direction perpendicular to an upper surface of the substrate, a first conductive pattern surrounding the conductive pillar, and a second conductive pattern between the first conductive pattern and the landing pad, and the dielectric layer is in contact with of the first conductive pattern.

A semiconductor memory device according to some embodiments of the inventive concept may include a device isolation pattern defining an active pattern in a substrate, a pair of word lines crossing the active pattern, a bit line electrically connected to a central portion of the active pattern between the pair of word lines, landing pads each connected with edge portions of the active pattern spaced apart from the central portion, bottom capacitor electrodes each of which is electrically connected to a corresponding one of the landing pads, a support pattern between the bottom capacitor electrodes and connecting the bottom capacitor electrodes, a top capacitor electrode covering the bottom capacitor electrodes and the support pattern, and a capacitor dielectric layer between the bottom capacitor electrode and the top capacitor electrode, wherein the bottom capacitor electrode includes a conductive pillar and a first conductive pattern surrounding the conductive pillar, the first conductive pattern includes a first material including a first element and doped with a second element, the conductive pillar comprises a second material including the first element and doped with the second element, and the first material and the second material have different atomic percentage ratios of the first element to the second element. The first element is different from the second element.

A semiconductor memory device according to some embodiments of the inventive concept may include a cell transistor provided with a substrate; a first capacitor electrode on the substrate, the first capacitor electrode being directly electrically connected to the cell transistor; a second capacitor electrode on the first capacitor electrode; and a capacitor dielectric layer between the first capacitor electrode and the second capacitor electrode. The first capacitor electrode comprises a conductive pillar, a first conductive pattern and a second conductive pattern, the first conductive pattern surrounds the conductive pillar, the second conductive pattern is disposed between the cell transistor and the first conductive pattern, and the second conductive pattern is in contact with a side surface of the first conductive pattern. The conductive pillar comprises a first material, the first conductive pattern comprises a second material including a first element, and the second conductive pattern comprises the first material. The conductive pillar further comprises a second element and the first element, and the first conductive pattern further comprises the second element. The conductive pillar has a greater atomic percentage of the second element than the first conductive pattern, and the first conductive pattern has a greater atomic percentage of the first element than the conductive pillar.

A method for manufacturing a semiconductor memory device according to some embodiments of the inventive concept may include alternately forming mold layers and support layers on a substrate, forming an electrode hole penetrating the mold layers and the support layers, and forming a bottom electrode in the electrode hole, wherein forming the bottom electrode includes forming a first conductive pattern and a conductive pillar on the first conductive pattern, and forming the first conductive pattern and the conductive pillar includes doping an impurity into the first conductive pattern and the conductive pillar.

In the method for manufacturing a semiconductor memory device according to an embodiment, an impurity doped into the conductive pillar may be a first material, and an impurity doped into the first conductive pattern may be a second material different from the first material.

In the method for manufacturing a semiconductor memory device according to an embodiment, the first material may include niobium, and the second material may include silicon.

In the method for manufacturing a semiconductor memory device according to an embodiment, forming the bottom electrode may include forming a second conductive pattern in the electrode hole before forming the first conductive pattern.

In the method for manufacturing a semiconductor memory device according to an embodiment, forming the bottom electrode may include removing a portion of the second conductive pattern to expose a portion of a side surface of the first conductive pattern.

In the method for manufacturing a semiconductor memory device according to an embodiment, may further include forming a dielectric layer on the bottom electrode, wherein the dielectric layer is formed on the exposed portion of the side surface of the first conductive pattern.

### BRIEF DESCRIPTION OF THE DRAWINGS

FIG. 1 is a block diagram of a semiconductor memory device according to embodiments of the inventive concept.

FIG. 2 is a diagram of a semiconductor memory device according to embodiments of the inventive concept, and is an enlarged plan view of the P1 region of FIG. 1.

FIGS. 3A and 3B are diagrams illustrating a semiconductor memory device according to embodiments of the inventive concept, and are cross-sectional views taken along line A-A′ and line B-B′ in FIG. 2.

FIG. 4 is an enlarged view of the P2 region of FIG. 3A.

FIG. 5 is a graph showing atomic percentages of specific elements measured along the line C-C′ in FIG. 4.

FIGS. 6A, 6B, 7A, 7B, 8A, 8B, 9A, 9B, 10A, 10B, 11A, 11B, 12A and 12B are diagrams for describing a method for manufacturing a semiconductor memory device according to embodiments of the inventive concept.

### DETAILED DESCRIPTION

Example embodiments of the inventive concepts will now be described more fully with reference to the accompanying drawings, in which example embodiments are shown.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as "including" a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, 'same' and 'equal' may encompass identicality or near

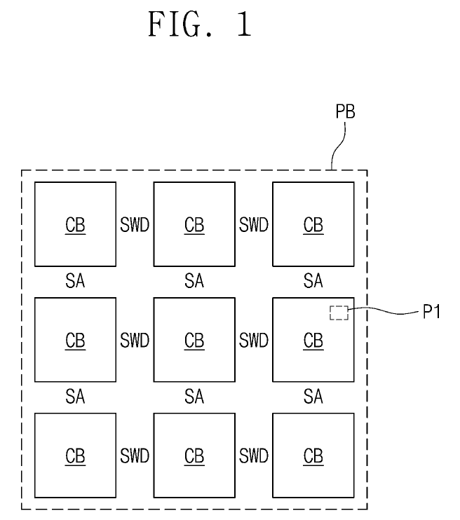

FIG. 1 is a block diagram of a semiconductor memory device according to embodiments of the inventive concept.

Referring to FIG. 1, a semiconductor memory device may include cell blocks CB and a peripheral block PB surrounding each of the cell blocks CB. Each of the cell blocks CB may include a cell circuit, such as a memory integrated circuit. The peripheral block PB may include various peripheral circuits required for the operation of the cell circuit. The peripheral circuits of the peripheral block PB may be electrically connected to the cell circuit of each of the cell blocks CB. For example, each of the cell blocks CB may include a cell array including a plurality of unit memory cells, and each of the unit memory cells may include a cell transistor and a capacitor.

The peripheral block PB may include sense amplifier circuits SA and sub-word line driver circuits SWD. For example, each of the sense amplifier circuits SA and the sub-word line driver circuits SWD may be located between cell blocks CB adjacent to each other. The peripheral block PB may further include power supply for sense amplifier driving and ground driver circuits.

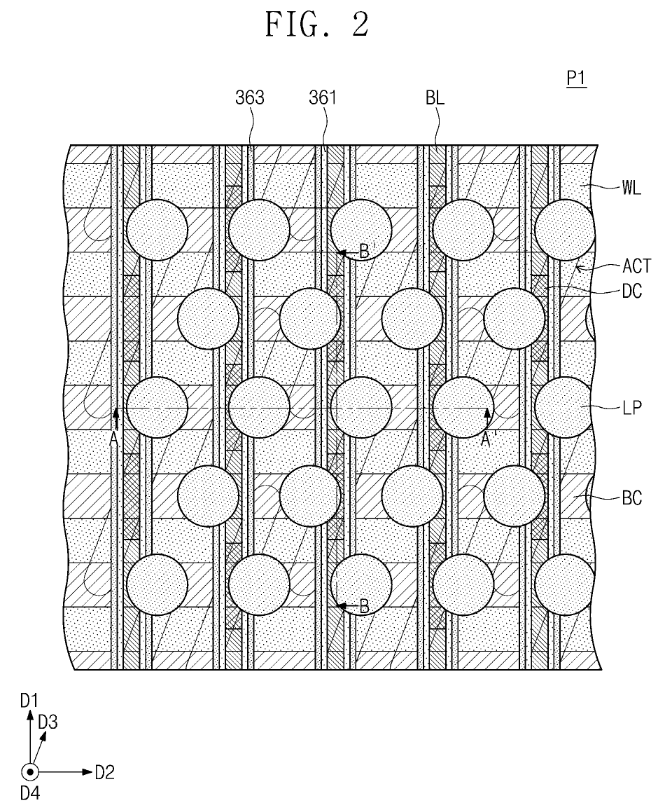

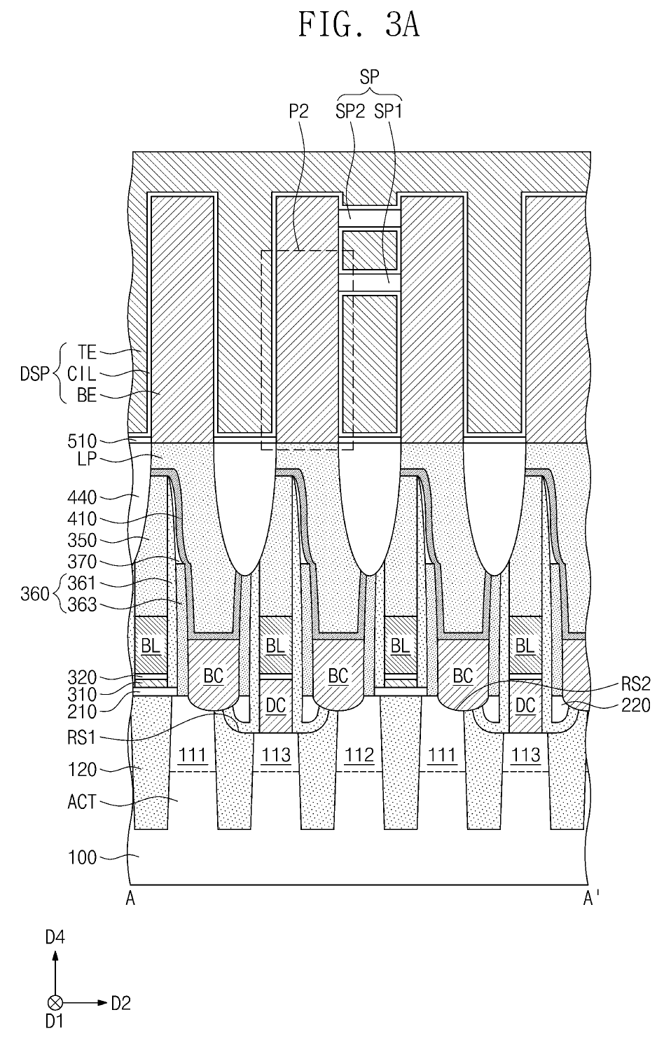

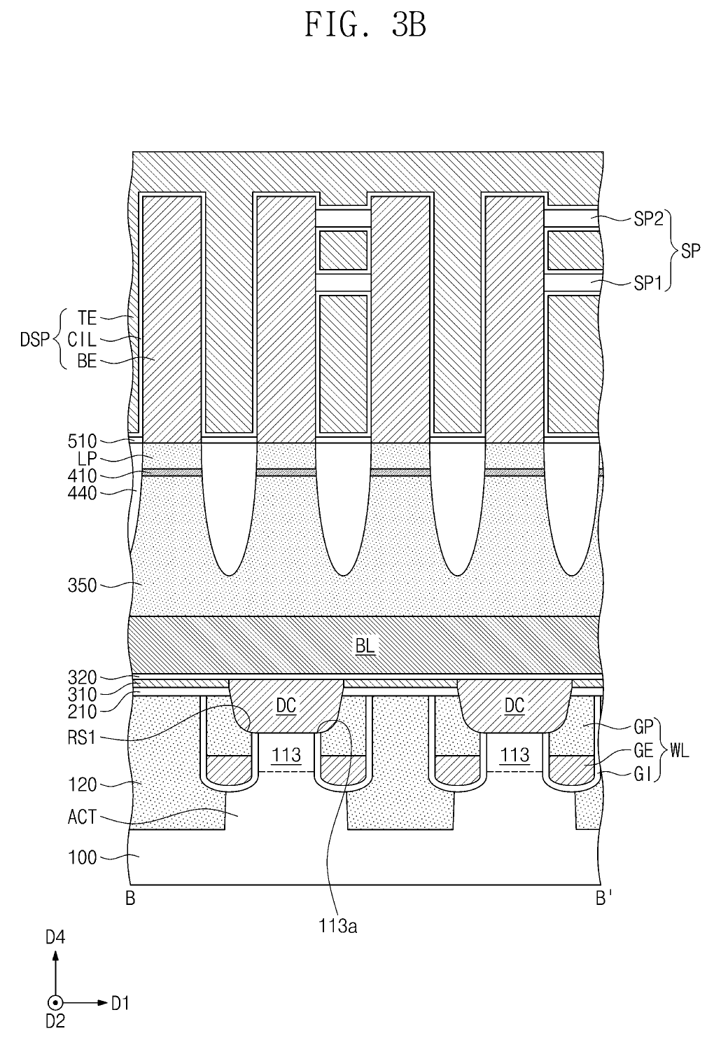

FIG. 2 is a diagram of a semiconductor memory device according to embodiments of the inventive concept, and is an enlarged plan view of a P1 region of FIG. 1. FIGS. 3A and 3B are diagrams illustrating a semiconductor memory device according to embodiments of the inventive concept, and are cross-sectional views taken along line A-A′ and line B-B′ in FIG. 2.

Referring to FIGS. 2, 3A, and 3B, a substrate 100 may be provided. The substrate 100 may be a semiconductor substrate. For example, the semiconductor substrate may include a silicon substrate, a germanium substrate, or a silicon-germanium substrate, but is not limited thereto.

A device isolation pattern 120 defining active patterns ACT may be provided in the substrate 100. The active patterns ACT may be disposed to be spaced apart from each other in a first direction D1 and a second direction D2. In the present specification, the first direction D1, the second direction D2, and a third direction D3 may intersect each other. The first direction D1, the second direction D2, and the third direction D3 may be parallel to an upper surface or a lower surface of the substrate 100. For example, the first direction D1 and the second direction D2 may be orthogonal to each other, and the third direction D3 may intersect with the first and second directions D1 and D2. The fourth direction D4 may be perpendicular to the upper surface or the lower surface of the substrate 100. For example, the fourth direction D4 may be orthogonal to the first direction D1, the second direction D2, and the third direction D3.

The device isolation pattern 120 may include an insulating material. For example, the insulating material may be at least one of silicon oxide or silicon nitride, or a combination thereof. In the present specification, each of the phrases such as “A or B”, “at least one of A and B”, “at least one of A or B”, "A, B, or C”, “at least one of A, B, and C”, and “at least one of A, B or C” may include any one of the items listed together in the corresponding one of the phrases, or all possible combinations thereof.

Active patterns ACT may be provided in the substrate 100. Each of the active patterns ACT may have an island shape separated from each other. Each of the active patterns ACT may have a bar shape elongated in the third direction D3. In a plan view, the active patterns ACT may be surrounded by the device isolation pattern 120. For example, the active patterns ACT may be a portion of the substrate 100 that protrudes in the fourth direction D4 perpendicular to the upper surface of the substrate 100. However, for convenience of description, the substrate 100 and the active patterns ACT are described as different elements. Reference to the substrate being provided with a cell transistor (or active pattern) is referred to with the intention of encompassing these embodiments.

Each of the active patterns ACT may include a pair of edge portions 111 and 112 and a central portion 113. The pair of edge portions 111 and 112 may include a first edge portion 111 and a second edge portion 112. The first edge portion 111 may be one of the ends of each of the active patterns ACT along the third direction D3. The second edge portion 112 may be another one of the ends of each of the active patterns ACT along an opposite direction to the third direction D3. The central portion 113 may be a portion of the active patterns ACT between the pair of edge portions 111 and 112. For example, the central portion 113 may be a portion of the active patterns ACT between a pair of word lines WL described below. Each of the upper surfaces of the pair of edge portions 111 and 112 may be located at a higher level than an upper surface of the central portion 113. Impurities (e.g., n-type or p-type impurities (charge carrier dopants)) may be doped in the pair of edge portions 111 and 112 and the central portion 113.

The word lines WL may be provided on the substrate 100. Each of the word lines WL may extend in the second direction D2 and may be spaced apart from each other in the first direction D1. The word lines WL may cross the active patterns ACT and the device isolation pattern 120. For example, a pair of word lines WL adjacent to each other in the first direction D1 may cross one of the active patterns ACT.

Each of the word lines WL may include a gate electrode GE, a gate insulating layer GI, and a gate capping pattern GP. The gate electrode GE may extend in the second direction D2 and cross the active patterns ACT and the device isolation pattern 120. The gate insulating layer GI may be provided between the gate electrode GE and the active patterns ACT, and between the gate electrodes GE and the device isolation pattern 120. The gate capping pattern GP may extend in the second direction D2 along the gate electrode GE on the gate electrode GE.

First recess regions RS1 may be provided on the central portion 113 of each of the active patterns ACT. The center portion 113 of the active patterns ACT, the device isolation pattern 120, and the capping pattern GP of the word lines WL may be partially exposed by the inner wall of the first recess regions RS1. For example, the active pattern ACT, the gate electrode GE and the gate insulating layer GI may form components of a cell transistor.

A buffer pattern 210 may be provided on the active patterns ACT and the device isolation pattern 120. The buffer pattern 210 may partially cover the active patterns ACT, the device isolation pattern 120, and the word lines WL. The buffer pattern 210 may not be provided on the central portion 113 of the active patterns ACT. For example, the buffer pattern 210 may include at least one of silicon oxide, silicon nitride, silicon oxynitride, and a combination thereof.

Bit lines BL may be provided on the device isolation pattern 120 and the active patterns ACT. The bit lines BL may be located on the word lines WL. Each of the bit lines BL may extend in the first direction D1 and may be spaced apart from each other in the second direction D2. Each of the bit lines BL may cross the central portion 113 of the active patterns ACT adjacent to the first direction D1. The bit lines BL may include a metallic material. For example, the bit lines BL may include at least one of tungsten, rubidium, molybdenum, titanium, and a combination thereof.

Bit line contacts DC may be provided on active patterns ACT. Each of the bit line contacts DC may be located on a central portion 113 of each of the active patterns ACT. The bit line contacts DC may be spaced apart from each other in the first and second directions D1 and D2. For example, each of the bit line contacts DC may be located between the central portion 113 of the active patterns ACT and the bit lines BL. The bit line contacts DC may electrically connect the corresponding bit lines BL to the central portion 113 of the active patterns ACT. The bit line contacts DC may include at least one of an impurity-doped polysilicon, an undoped polysilicon, a metal material, and a combination thereof.

Each of the bit line contacts DC may be located in the first recess regions RS1, and fill a portion of the first recess regions RS1. Lower buried insulating patterns 220 may be provided in the first recess regions RS1 adjacent to the bit line contacts DC. The lower buried insulating patterns 220 may fill the remaining portion of the first recess regions RS1.

Polysilicon patterns 310 may be located between the bit lines BL and the buffer pattern 210, and between bit line contacts DC adjacent to each other in the first direction D1. The polysilicon patterns 310 may be connected to each of the bit line contacts DC adjacent to each other in the first direction D1. For example, upper surfaces of the polysilicon patterns 310 may be located at substantially the same level as upper surfaces of the bit line contacts DC.

Ohmic patterns 320 may be provided between the bit lines BL and the bit line contacts DC, and between the bit lines BL and the polysilicon patterns 310. The ohmic patterns 320 may extend along the bit lines BL in the first direction D1 and may be spaced apart from each other in the second direction D2. For example, the ohmic patterns 320 may include a metal silicide.

Bit line capping patterns 350 may be provided on the bit lines BL. The bit line capping patterns 350 may extend along the corresponding bit lines BL in the first direction D1 and may be spaced apart from each other in the second direction D2. In a plan view, each of the bit line capping patterns 350 may overlap the corresponding bit lines BL. The bit line capping patterns 350 may be composed of a single layer or multiple layers. For example, the bit line capping patterns 350 may include silicon nitride.

Bit line spacers 360 may be provided on both sides (or opposite sides) of the bit line capping patterns 350 and the bit lines BL. The bit line spacers 360 may cover side surfaces of the bit lines BL and side surfaces of the bit line capping patterns 350. For example, each of the bit line spacers 360 may include a first bit line spacer 361 and a second bit line spacer 363. The second bit line spacer 363 may be located on both sides (or opposite sides) of the bit lines BL and the bit line capping patterns 350. The first bit line spacer 361 may be provided between the bit lines BL and the second bit line spacer 363 and between the bit line capping patterns 350 and the second bit line spacer 363. For example, the first and second bit line spacers 361 and 363 may each include at least one of silicon nitride, silicon oxide, silicon oxynitride, and a combination thereof.

Capping spacers 370 may be located on the bit line spacers 360. For example, each of the capping spacers 370 may cover an upper surface of the second bit line spacer 363 and a side surface of the first bit line spacer 361 of each of the corresponding bit line spacers 360. For example, the capping spacers 370 may include silicon nitride.

Each of a storage node contacts BC may be provided between the bit lines BL adjacent to each other in the second direction D2. The storage node contacts BC may be spaced apart from each other in the first and second directions D1 and D2. Each of the word lines WL may be provided between the storage node contacts BC adjacent to each other in the first direction D1. Each of the bit lines BL may be provided between the storage node contacts BC adjacent to each other in the second direction D2. Each of the storage node contacts BC may fill second recess regions RS2 provided on the edge portions 111 and 112 of the active patterns ACT. The storage node contacts BC may be electrically connected with the corresponding edge portions 111 and 112. For example, the storage node contacts BC may include at least one of impurity doped polysilicon, undoped polysilicon, a metal material, and a combination thereof.

Barrier patterns 410 may be provided on the bit line capping patterns 350 and the storage node contacts BC. The barrier patterns 410 may cover the bit line capping patterns 350, the bit line spacers 360, the capping spacers 370, and the storage node contacts BC with a uniform thickness. For example, the barrier patterns 410 may include a conductive metal nitride such as titanium nitride, and tantalum nitride.

Landing pads LP may be provided on the storage node contacts BC. The landing pads LP may be spaced apart from each other in the first and second directions D1 and D2. Each of the landing pads LP may be electrically connected with the corresponding storage node contacts BC. Lower portions of the landing pads LP may vertically overlap the corresponding storage node contacts BC. Upper portions of the landing pads LP may be shifted in the second direction D2 from the lower portions of the landing pads LP. For example, the upper portions and lower portions of the landing pads LP may be offset. For example, the landing pads LP may include a metal material such as tungsten, titanium, tantalum, and the like.

A filling pattern 440 may cover side surfaces of the landing pads LP. The filling pattern 440 may be located between the landing pads LP. In a plan view, the filling pattern 440 may have a mesh shape including holes penetrated by the landing pads LP. For example, the filling pattern 440 may include at least one of silicon nitride, silicon oxide, silicon oxynitride, and a combination thereof. Alternatively, the filling pattern 440 may include an empty space (e.g., an air gap or an air layer). The term “air” as discussed herein, may refer to atmospheric air, or other gases that may be present during the manufacturing process. An “air gap” may comprise a gap having air, and/or other gasses that are present during the manufacturing process, or a gap forming a vacuum therein.

A data storage pattern DSP may be provided on the landing pads LP. The data storage pattern DSP may include bottom electrodes BE, a top electrode TE covering the bottom electrodes BE, and a dielectric layer CIL between the bottom electrodes BE and the top electrode TE. According to an embodiment, an etch stop layer 510 covering the filling pattern 440 may be provided between the bottom electrodes BE. For example, the data storage pattern DSP may be a capacitor, the dielectric layer CIL may be a capacitor dielectric, and the top electrode TE and the bottom electrodes BE may be capacitor electrodes. The data storage pattern DSP may be a component of a unit memory cell that stores data.

For example, the bottom electrodes BE may be directly electrically connected to a corresponding one of the active patterns ACT (or cell transistors). As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Each of the bottom electrodes BE may vertically overlap with an upper portion of the corresponding landing pads LP, and may be connected with (or to) the landing pads LP. The bottom electrodes BE may be spaced apart from each other in the first and second directions D1 and D2. In a plan view, the bottom electrodes BE may be disposed (or arranged) in a honeycomb shape. In addition, each of the bottom electrodes BE may have a shape extending in the fourth direction D4 perpendicular to the upper surface of the substrate 100.

Support patterns SP may be provided between the bottom electrodes BE adjacent to each other. The support patterns SP may be located on side surfaces of the bottom electrodes BE. The support patterns SP may connect the bottom electrodes BE adjacent to each other. The support patterns SP may include a first support pattern (or a first subsidiary support pattern) SP1 and a second support pattern (or a second subsidiary support pattern) SP2 on the first support pattern SP2. The first support pattern SP1 and the second support pattern SP2 may be spaced apart from each other in the fourth direction D4. Therefore, the top electrode TE may be filled between the first support pattern SP1 and the second support pattern SP2. For example, the support patterns SP may include at least one of silicon nitride, silicon boron nitride, and silicon carbonitride.

The dielectric layer CIL between the bottom electrodes BE and the top electrode TE may cover the bottom electrodes BE with a uniform thickness. The dielectric layer CIL may extend on the bottom electrodes BE, the etch stop layer 510 and the support patterns SP. For example, the dielectric layer CIL may include silicon oxide and/or a material having a higher dielectric constant than silicon oxide. More specifically, the dielectric layer CIL may include a metal oxide such as aluminum oxide.

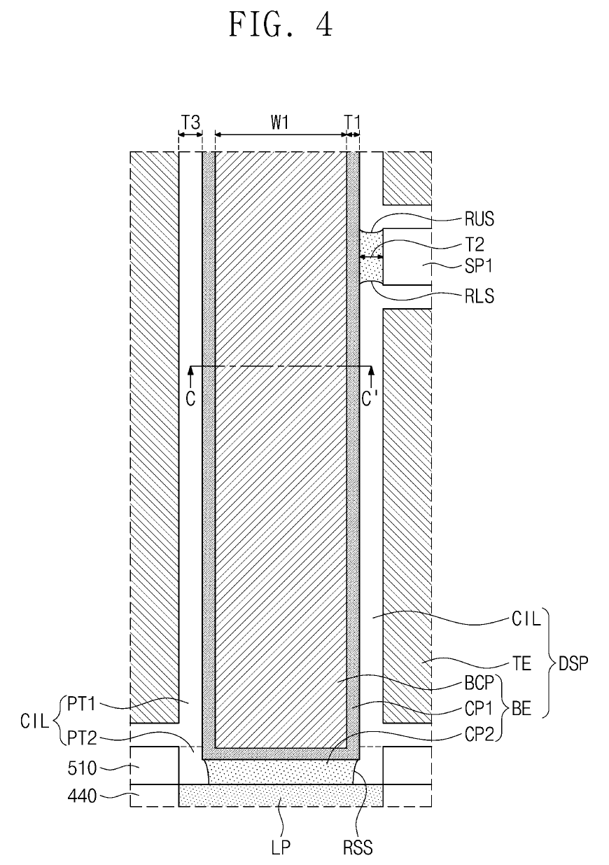

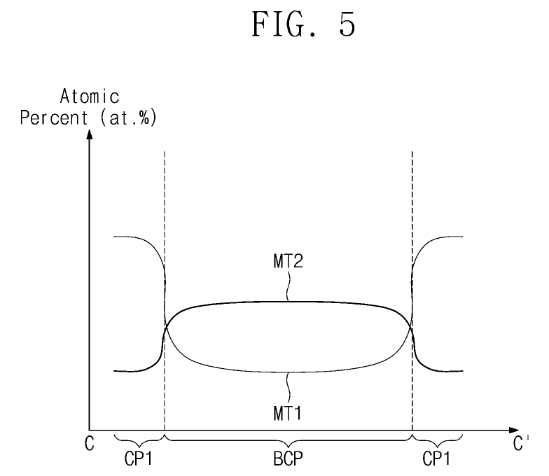

FIG. 4 is an enlarged view of the P2 region of FIG. 3A. FIG. 5 is a graph showing the atomic percentages of impurities (or specific elements) measured along the line C-C′ in FIG. 4.

Referring to FIG. 4, the bottom electrode BE of the data storage pattern DSP may include a conductive pillar BCP, a first conductive pattern CP1, and a second conductive pattern CP2.

The conductive pillar BCP of the bottom electrode BE may extend in a direction perpendicular to the upper surface of the substrate 100 of FIGS. 3A and 3B. The conductive pillar BCP may have a first width W1 in a horizontal direction. An impurity (or element) may be doped in the conductive pillar BCP. In some embodiments, the material of the conductive pillar (BCP) may be crystalline in nature (e.g., the constituent atoms are arranged in a periodic lattice). For example, the material of the conductive pillar (BCP) may be continuous and homogeneous in composition and structure. The impurity may be a crystalline defect such as, without limitation, interstitial defects (occupying a site between regular lattice points) and substitutional defects (e.g., a lattice atom is replaced by an atom of a different element). For example, if the impurity is a particle (or dopant atom) smaller than titanium, the impurity may exist as an interstitial defect in the conductive pillar BCP. If the impurity is a particle (or dopant atom) larger than titanium, the impurity may exist (or present) as a substitutional defect in the conductive pillar BCP. The impurity doped in the conductive pillar BCP may disturb a lattice dislocation of elements constituting the conductive pillar BCP. For example, the impurity doped in the conductive pillar BCP may induce a lattice defect (e.g., dislocation) in the material constituting the conductive pillar BCP Therefore, a physical hardness of the conductive pillar BCP may be improved (e.g., increased). For example, the impurity doped in the conductive pillar BCP may include at least one of niobium, tantalum, and vanadium. For example, when the conductive pillar BCP is formed of crystalline, and doped with an impurity (e.g., niobium or tantalum) larger than titanium as a substitutional defect, the hardness of the BCP pillar is increased as compared to an identical material that is not doped with such an impurity. The impurity doped in the conductive pillar BCP may not be a charge carrier dopant (i.e., is neither an n-type dopant or a p-type dopant) and in such instance, does not affect the conductivity of the conductive pillar BCP.

The first conductive pattern CP1 of the bottom electrode BE may cover the conductive pillar BCP with a uniform thickness. The first conductive pattern CP1 may cover side surfaces and a lower surface of the conductive pillar BCP with a first thickness T1. For example, the conductive pillar BCP may be provided inside of the first conductive pattern CP1. When the first conductive pattern CP1 may have a shape of a cylinder with an empty interior, the conductive pillar BCP may have a shape of pillar filling the empty interior of the first conductive pattern CP1. An impurity may be doped in the first conductive pattern CP1. The impurity doped in the first conductive pattern CP1 may disturb a lattice dislocation of elements constituting the first conductive pattern CP1. Therefore, a physical hardness of the first conductive pattern CP1 may be improved. For example, the impurity doped in the first conductive pattern CP1 may include at least one of silicon, tantalum, and vanadium.

The second conductive pattern CP2 of the bottom electrode BE may be provided between the first conductive pattern CP1 and the landing pad LP and between the first conductive patterns CP1 and the first support patterns SP1. The second conductive pattern CP2 may cover a portion of the first conductive pattern CP1 with a uniform thickness. For example, the second conductive pattern CP2 may cover the lower surface of the first conductive pattern CP1 and a portion of a side surface of the first conductivity pattern CP1 with a second thickness T2. In a method for manufacturing a semiconductor memory device to be described later, the second conductive pattern CP2 may be used as a seed layer for forming the first conductive pattern CP1. In addition, the second conductive pattern CP2 may be a shield layer for protecting the first conductive pattern CP1 in the process of removing the mold layer. Thereafter, the second conductive pattern CP2 may be partially removed to expose the remaining portion of the side surface of the first conductive pattern CP1. According to an embodiment, the second conductive pattern CP2 may include TiN.

A portion of the second conductive pattern CP2 between the first conductive pattern CP1 and the landing pad LP may be in contact with the first conductive pattern CP1 and the landing pad LP. The portion of the second conductive pattern CP2 may have side surfaces RSS recessed therein. The remaining portion of the second conductive pattern CP2 between the first conductive pattern CP1 and the first support pattern SP1 may be in contact with the first conductive pattern CP1 and the first support pattern SP1. The remaining portion of the second conductive pattern CP2 may have an upper surface RUS and a lower surface RLS recessed therein. For example, the recessed side surfaces RSS and the recessed upper and lower surfaces RUS and RLS of the second conductive pattern CP2 may be curved surfaces, but are not limited thereto. The second conductive pattern CP2 may also be provided on a side surface of the second support pattern SP2 as described with reference to FIGS. 3A and 3B.

According to an embodiment, the first width W1 of the conductive pillar BCP may be greater than the second thickness T2 of the second conductive pattern CP2 and the first thickness T1 of the first conductive pattern CP1. The second thickness T2 of the second conductive pattern CP2 may be different from the first thickness T1 of the first conductive pattern CP1. For example, the second thickness T2 of the second conductive pattern CP2 may be greater than the first thickness T1 of the first conductive pattern CP1. The second thickness T2 of the second conductive pattern CP2 may be 30 Å to 80 Å, and the first thickness T1 of the first conductive pattern CP1 may be 10 Å to 20 Å.

The dielectric layer CIL of the data storage pattern DSP may be provided on the first conductive pattern CP1 of the bottom electrode BE and between the bottom electrode BE and the top electrode TE. In a method for manufacturing a semiconductor memory device described later, the dielectric layer CIL may be formed on the first conductive pattern CP1. The first conductive pattern CP1 may have a lattice constant substantially similar to the dielectric layer CIL. Accordingly, the dielectric layer CIL having excellent crystallinity may be formed easily. Accordingly, electrical characteristics of the semiconductor memory device may be improved.

The dielectric layer CIL may include a first portion PT1 having a uniform thickness and a second portion PT2 having a nonuniform thickness. The first portion PT1 of the dielectric layer CIL may extend on the upper surface of the etching stop layer 510 and the upper and lower surfaces of the first support pattern SP1 on the side surface of the first conductive pattern CP1. The first portion PT1 of the dielectric layer CIL may be in contact with the upper surface of the etching stop layer 510 and the upper and lower surfaces of the first support pattern SP1. In addition, the first portion PT1 of the dielectric layer CIL may cover the recessed upper and lower surfaces RUS and RLS of the remaining portion of the second conductive pattern CP2 between the first conductive pattern CP1 and the first support pattern SP1. For example, the first portion PT1 of the dielectric layer CIL may have a third thickness T3. The third thickness T3 of the first portion PT1 may be 30 Å to 80 Å. The second portion PT2 of the dielectric layer CIL may fill a space between the etch stop layer 510 and the portion of the second conductive pattern CP2, which is between the first conductive pattern CP1 and the landing pad LP. The second portion PT2 of the dielectric layer CIL may extend on recessed side surfaces RSS of the portion of the second conductive pattern CP2 and cover the recessed side surfaces RRS.

The thicknesses T1, T2 and T3 may be the distances between the opposite major surfaces of the first conductive pattern CP1, the second conductive pattern CP2 and the dielectric layer CIL, respectively. The thicknesses T1, T2 and T3 may be measured in a direction perpendicular to the local surface of the conductive pillar BCP at the point of measurement. Accordingly, the measurement direction may vary depending on the location. For example, the portion of the second conductive pattern CP2, which is in contact with the landing pad LP, may be measured in a direction perpendicular to the substrate. On the other hand, another portion (e.g., the portion in contact with the first support pattern SP1) of the second conductive pattern CP2 may be measured in a direction parallel to the top surface of the substrate, as indicated in the drawings.

For example, the thicknesses T1, T2 and T3 may be the minimum distances between the opposite major surfaces of the first conductive pattern CP1, the second conductive pattern CP2 and the dielectric layer CIL, respectively.

Referring to FIG. 5, the conductive pillar BCP may include a second material (or element) MT2 doped with a first material (or element) MT1. The first conductive pattern CP1 may include the first material MT1 doped with the second material MT2. For example, the first material MT1 may be a material constituting the first conductive pattern CP1 while corresponding to an impurity doped in the conductive pillar BCP. In addition, the second material MT2 may be a material constituting the conductive pillar BCP while corresponding to an impurity doped in the first conductive pattern CP1.

More specifically, the first material MT1 and the second material MT2 may be in the conductive pillar BCP and the first conductive pattern CP1, but atomic percentages (at. %) of the first material MT1 and the second material MT2 may be different in the conductive pillars BCP and the second conductive pattern CP1. Each of the first material MT1 and the second material MT2 may have a specific atomic percentage in each of the first conductive pattern CP1 and the conductive pillar BCP. The atomic percentage of the first material MT1 may be relatively high in the first conductive pattern CP1 and relatively low in the conductive pillar BCP. The atomic percentage of the second material MT2 may be relatively high in the conductive pillar BCP and relatively low in the first conductive pattern CP1. For example, the atomic percentage of the first material MT1 in the conductive pillar BCP may be 0.1 at. % to 30 at. %. The atomic percentage of the second material MT2 in the first conductive pattern CP1 may be from 0.1 at. % to 30 at. %.

According to an embodiment, the first material (or element) MT1 may include niobium, and the second material (or element) MT2 may include silicon. More specifically, the first conductive pattern CP1 may include NbN doped with silicon. The conductive pillar BCP may include TiSiN doped with niobium.

According to an embodiment, an impurity may be doped in any one of the conductive pillar BCP and the first conductive pattern CP1. Alternatively, the impurity doped in the conductive pillar BCP and the first conductive pattern CP1 may include different materials. For example, two or more different materials may be doped in at least one of the conductive pillar BCP and the first conductive pattern CP1.

Referring again to FIGS. 4 and 5, the bottom electrode BE of the semiconductor memory device may include the conductive pillar BCP and the first conductive pattern CP1 surrounding the conductive pillar BCP. The impurity doped in at least one of the conductive pillar BCP and the first conductive pattern CP1 may prevent a lattice dislocation from being generated in the conductive pillar BCP and the first conductive patterns CP1. Therefore, the physical hardness of the bottom electrode BE may be improved.

By improving the physical hardness of the bottom electrode BE having a large aspect ratio, warpage of the bottom electrode BE may be prevented or suppressed. Therefore, the bottom electrodes BE adjacent to each other may be prevented from being physically in contact with or electrically connected to each other. Accordingly, electrical characteristics and durability of the semiconductor memory device may be improved.

In some embodiments, the first conductive pattern CP1 may include a first material including a first element MT1 and a second element MT2. The conductive pillar BCP may include a second material including the first element MT1 and the second element MT2. The first material and the second material may have different atomic percentage ratios of the first element MT1 to the second element MT2, as shown in FIG. 5. For example, the second element MT2 may be silicon, and the first element MT1 may be niobium.

In some embodiments, the bottom electrode BE may include a conductive pillar BCP, a first conductive pattern CP1 and a second conductive pattern CP2. The second conductive pattern CP2 may be disposed between a cell transistor and the first conductive pattern, and the second conductive pattern CP2 may be partially in contact with a side surface of the first conductive pattern CP1. The conductive pillar BCP may include a first material (e.g., titanium nitride), the first conductive pattern CP1 may include a second material including a first element MT1 (e.g., niobium). The second conductive pattern CP2 may include the first material (e.g., titanium nitride). The conductive pillar BCP may further include a second element (e.g., silicon) and the first element (e.g., niobium) as impurities (or as dopants). The first conductive pattern CP1 may further include the second element (e.g., silicon) as impurities (or as dopants). The conductive pillar BCP may have a greater atomic percentage of the second element than the first conductive pattern CP1. The first conductive pattern CP1 may have a greater atomic percentage of the first element than the conductive pillar BCP. For example, the second material may be niobium nitride. For example, the first element and the second element may be a transition metallic element and a semiconductor element, respectively.

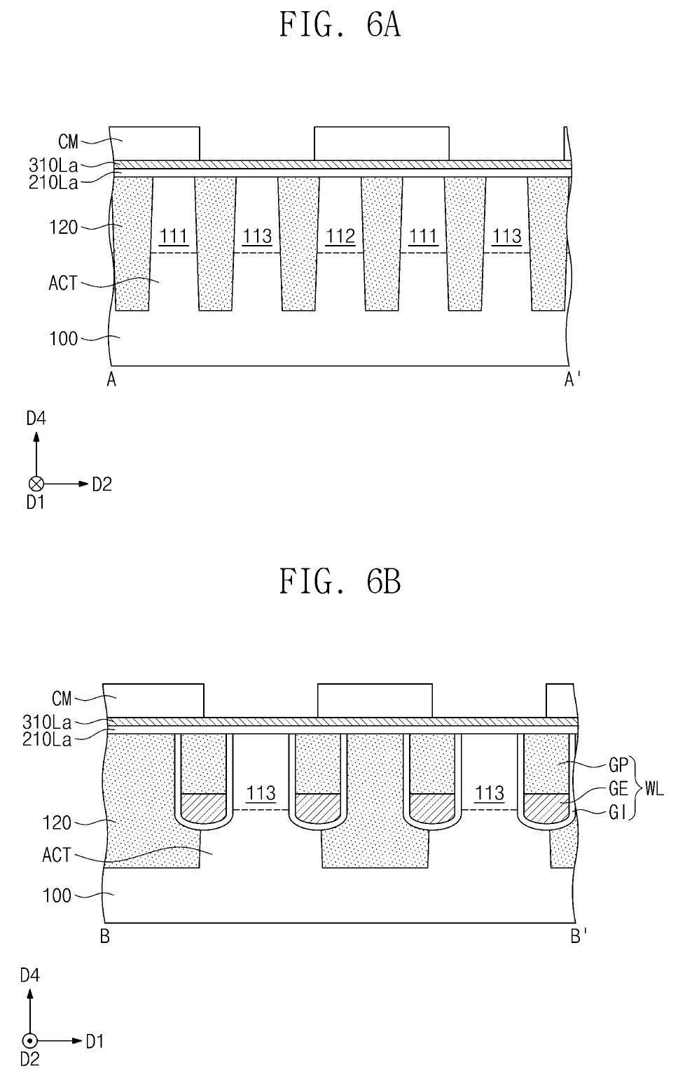

FIGS. 6A to 12B are diagrams for describing a method of manufacturing a semiconductor memory device according to embodiments of the inventive concept. FIGS. 6A, 7A, 8A, 9A, 10A, 11A, and 12A are cross-sectional views along line A-A′ of FIG. 2, and FIGS. 6B, 7B, 8B, 9B, 10B, 11B, and 12B are cross-sectional views along line B-B′ of FIG. 2.

Referring to FIGS. 6A and 6B, the device isolation pattern 120 and the active patterns ACT may be formed on the substrate 100. Forming the device isolation pattern 120 and the active patterns ACT may include forming a groove in the substrate 100 by a patterning process, filling the groove with an insulating material, and forming the device isolation patterns 120 by a planarization process. Portions of the substrate 100 in which no groove is formed may become the active patterns ACT.

The word lines WL may be formed on the device isolation pattern 120 and the active patterns ACT. Forming the word lines WL may include forming mask patterns on the active patterns ACT and the device isolation pattern 120, performing an anisotropic etch process using the mask patterns to form trenches, and filling the trenches with the word lines WL. Each of the word lines WL may be spaced apart from each other in the first direction D1 and may extend in the second direction D2 in the active patterns ACT.

Forming the word lines WL may include forming the gate insulating layer GI with a uniform thickness on an inner surface of each of the trenches, filling an inside of the trenches with a conductive layer, forming a gate electrode GE through an etch-back and/or polishing process for the conductive layer, and forming a gate capping pattern GP filling the trenches on the gate electrode GE. Each of the active patterns ACT may overlap with a pair of word lines WL. The central portion 113 of the active patterns ACT may be defined between the pair of word lines WL. The remaining portions of the active patterns ACT spaced apart from the central portion 113 with each of the pair of word lines WL therebetween may be defined as edge portions 111 and 112.

A first buffer layer 210La and a first polysilicon layer 310La may be sequentially formed on the substrate 100. The first buffer layer 210La and the first polysilicon layer 310La may cover the active patterns ACT, the device isolation pattern 120, and the word lines WL.

Contact mask patterns CM may be formed on the first polysilicon layer 310La. The contact mask patterns CM may be provided on the edge portions 111 and 112 of the active patterns ACT, and may not be provided on the central portion 113 of the active pattern ACT. The contact mask patterns CM may be spaced apart from each other in the first and second directions D1 and D2.

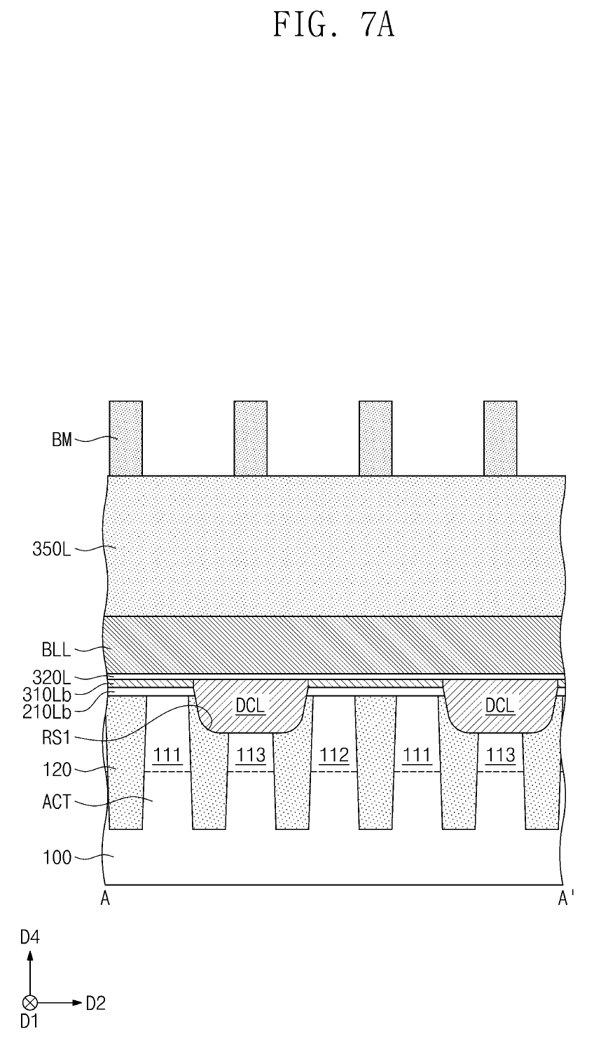

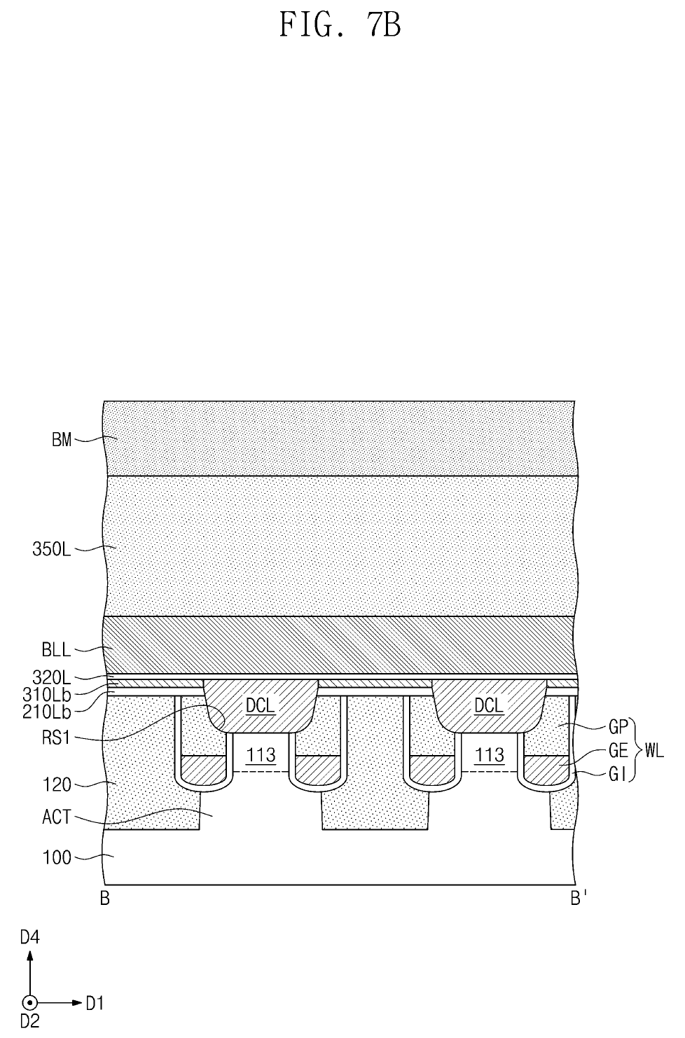

Referring to FIGS. 7A and 7B, first recess regions RS1 may be formed on the central portion 113 of the active patterns ACT. Forming the first recess regions RS1 may include performing an anisotropic etching process using the contact mask patterns CM as a mask. The first recess regions RS1 may partially expose the center portion 113 of the active patterns ACT, the word lines WL, and the device isolation pattern 120. The level of the upper surface of the central portion 113 of the active patterns ACT may be lowered by the anisotropic etching process.

The anisotropic etching process may remove a portion of the first buffer layer 210La and a portion of the second polysilicon layer 310La. Therefore, a second buffer layer 210Lb and a second polysilicon layer 310Lb may be formed from the first buffer layer 210La and the first polysilicon layer 310La, respectively.

Thereafter, bit line contact lines DCL may be formed to fill the first recess regions RS1. Forming the bit line contact lines DCL may include forming a bit line contact layer that fills the first recess regions RS1 covering the substrate 100, and removing an upper portion of the bit line contact layer to expose an upper surface of the second polysilicon layer 310Lb. Removing the upper portion of the bit line contact layer may be performed by a planarization process. As the upper portion of the bit line contact layer is removed, the bit line contact layer may be separated into the bit line contact lines DCL.

After the bit line contact lines DCL are formed, an ohmic layer 320L, a bit line layer BLL, a bit line capping layer 350L, and bit line mask patterns BM may be sequentially formed on the substrate 100. Each of the bit line mask patterns BM may extend in the first direction D1 and may be spaced apart from each other in the second direction D2.

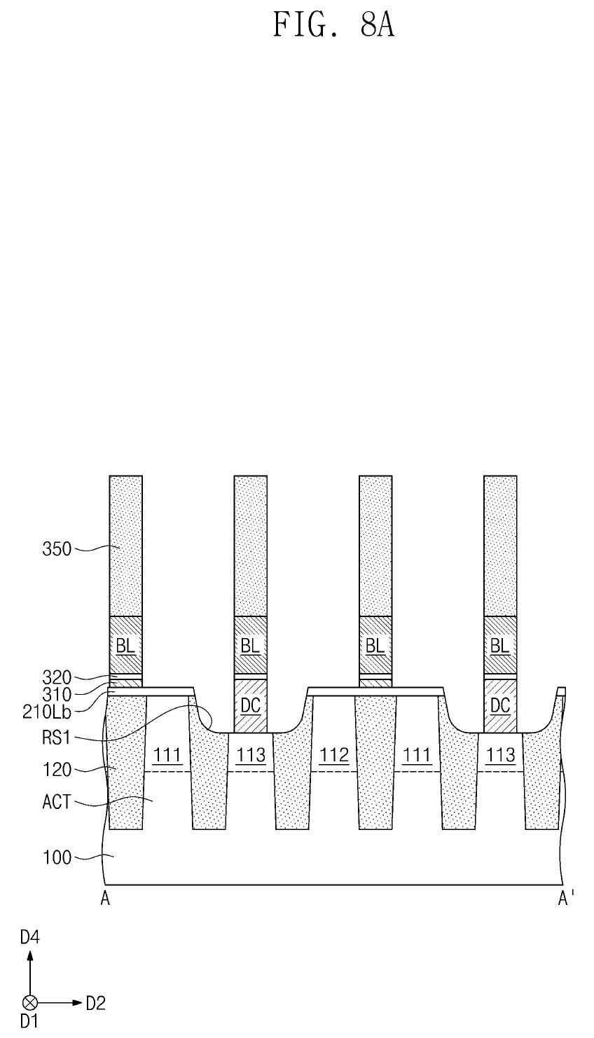

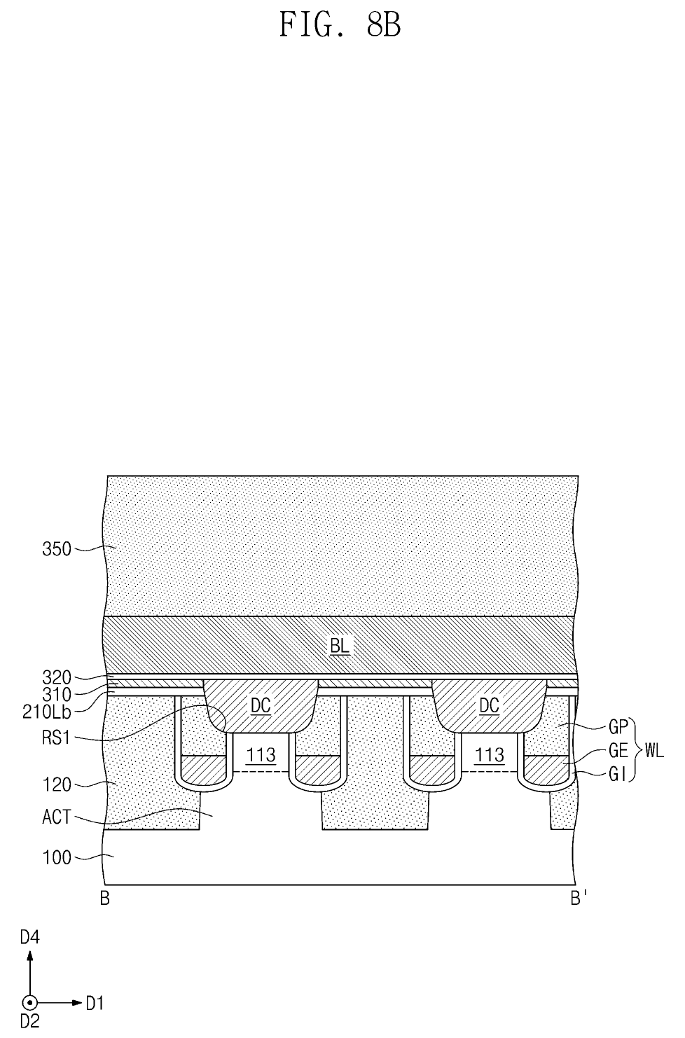

Referring to FIGS. 8A and 8B, bit line capping patterns 350, bit lines BL, ohmic patterns 320, bit line contacts DC, and polysilicon patterns 310 may be formed. Forming the bit line capping patterns 350, the bit lines BL, the ohmic patterns 320, the bit line contacts DC, and the polysilicon patterns 310 may include performing an anisotropic etch process using the bit line mask patterns BM as a mask. Each of the bit line capping patterns 350, the bit lines BL, the ohmic patterns 320, the bit line contacts DC, and the polysilicon patterns 310 may be formed from the bit line capping layer 350L, the bit line layer BLL, the ohmic layer 320L, the bit line contact lines DCL, and the second polysilicon layer 310Lb.

Through the anisotropic etching process, a portion of the inner wall of the first recess regions RS1 may be exposed to the outside. For example, the center portion 113 of the active patterns ACT and a portion of the device isolation pattern 120 may be exposed to the outside.

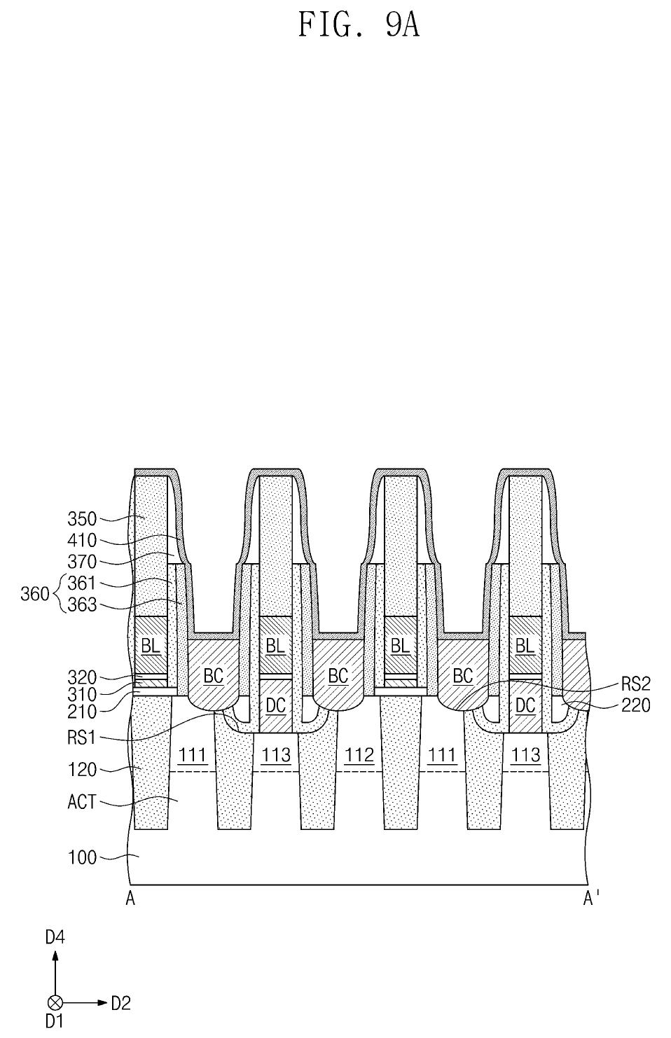

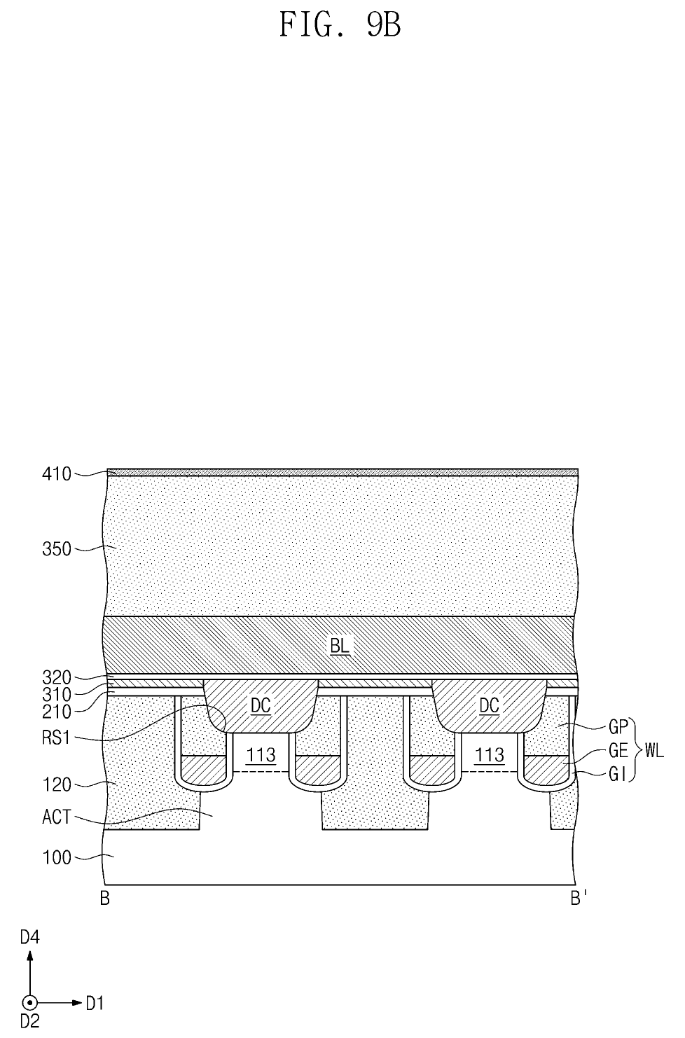

Referring to FIGS. 9A and 9B, bit line spacers 360 and lower buried insulation patterns 220 may be formed on the side surfaces of the bit lines BL and the side surfaces of the bit line capping patterns 350 exposed to the outside, and storage node contacts BC may be formed in second recess regions RS2.

More specifically, a first bit line spacer layer having a uniform thickness may be formed on the upper surface of the substrate 100, and a lower buried insulating layer filling the first recess regions RS1 may be formed. Then, a buffer pattern 210 may be formed from the second buffer layer 210Lb and the lower buried insulating patterns 220 may be formed from the lower buried insulating layer by the etching process performed.

A second bit line spacer layer may be formed on the first bit line spacer layer and the lower buried insulating patterns 220. The second recess regions RS2 may be formed by an etch-back process using the first and second bit line spacer layers.

The storage node contacts BC may be formed in the second recess regions RS2. The storage node contacts BC may be located between the bit lines BL adjacent to each other in the second direction D2. Each of the storage node contacts BC may be connected with edge portions 111 and 112 of the corresponding active patterns ACT. Forming the storage node contacts BC may include forming storage node lines that fill the second recess regions RS2, and performing an etch-back process on the storage node lines.

Portions of the first and second bit line spacer layers may be removed to form the first and second bit line spacers 361 and 363, by the etch-back process forming the storage node contacts BC. After that, capping spacers 370 may be formed on the first and second bit line spacers 361 and 363. Barrier patterns 410 may be formed to cover the bit line spacers 360, the capping spacers 370, the storage node contacts BC, and the bit line capping patterns 350 with a uniform thickness.

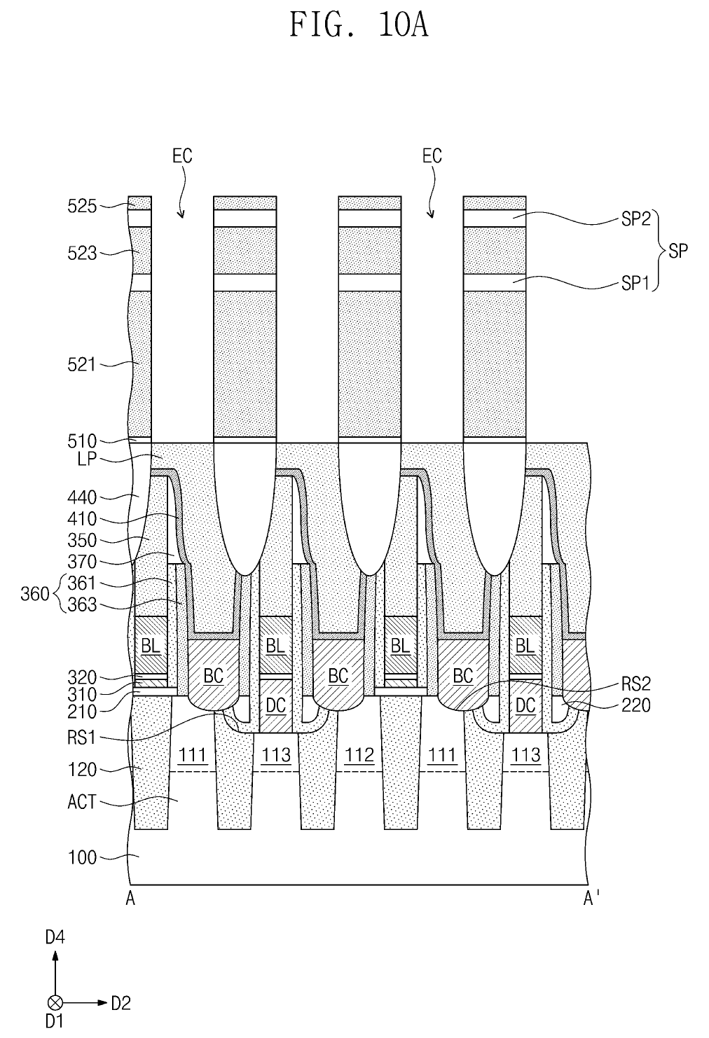

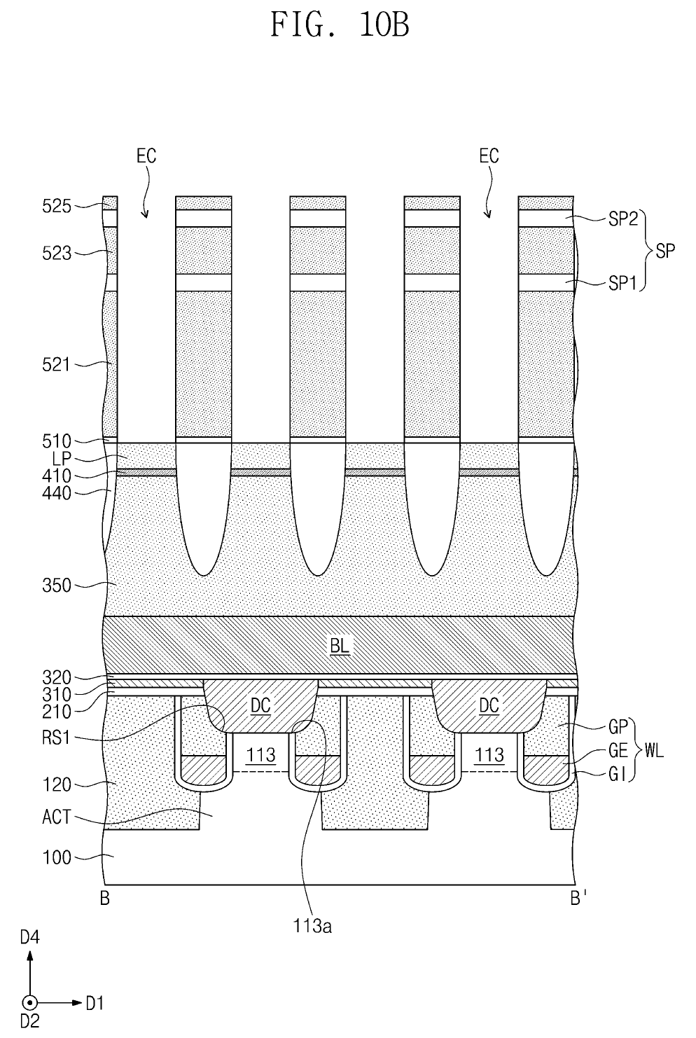

Referring to FIGS. 10A and 10B, landing pads LP may be formed on the storage node contacts BC. Forming the landing pads LP may include forming a landing pad layer and mask patterns covering the storage node contacts BC, and separating the landing pad layer into the landing pads LP through an anisotropic etching process using the mask patterns as a mask. As a result, the barrier patterns 410, the bit line spacers 360, and the bit line capping patterns 350 may be further partially removed. After that, the filling pattern 440 may be formed in a space removed by the etching process.

An etch stop layer 510, a first mold layer 521, a first support layer, a second mold layer 523, a second support layer, and a third mold layer 525 may be sequentially formed on the landing pads LP and the filling pattern 440. The first support layer may be located between the first mold layer 521 and the second mold layer 523, and the second support layer may be located between the second mold layer 523 and the third mold layer 525. The first support layer and the second support layer may include substantially the same material. The first mold layer 521, the second mold layer 523, and the third mold layer 525 may include substantially the same material, and the material may have an etch selectivity with respect to the first and second support layers. For example, the first to third mold layers 521, 523, and 525 may include silicon oxide, and the first and second support layers may include at least one of silicon nitride, silicon boron nitride, and silicon carbonitride.

Then, electrode holes EC penetrating through the first to third mold layers 521, 523, and 525 and the first and second support layers may be formed. Accordingly, a first support pattern SP1 and a second support pattern SP2 may be formed from the first and second support layers, respectively. Forming the electrode holes EC may include removing a portion of the etch stop layer 510. Thus, upper surfaces of the landing pads LP may be exposed again through the electrode holes EC.

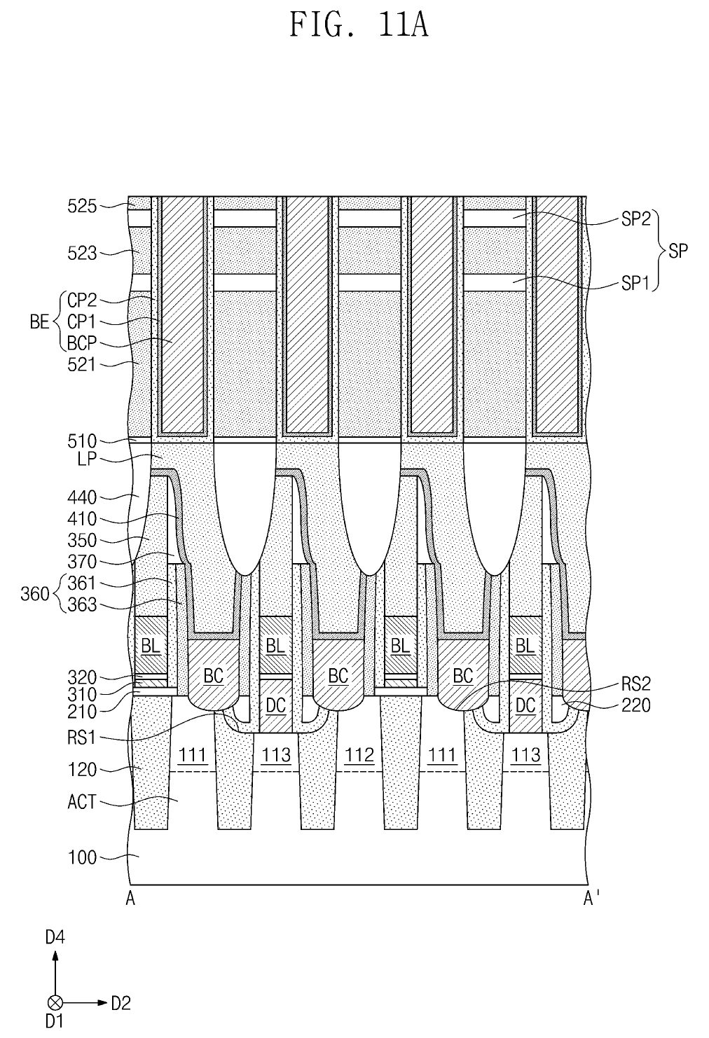

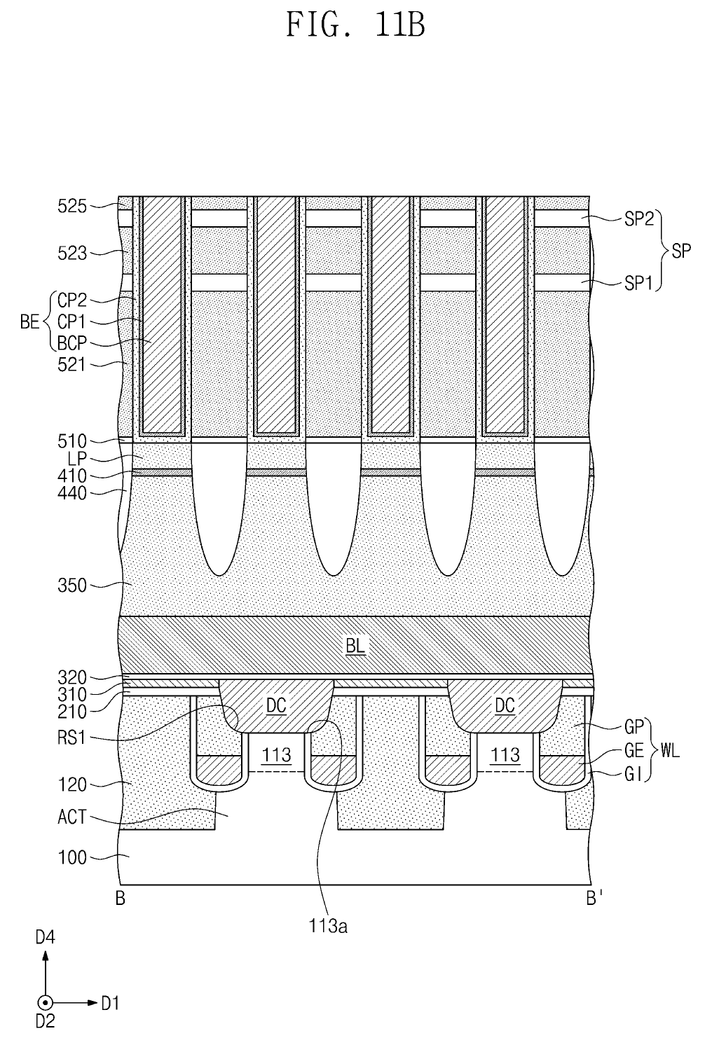

Referring to FIGS. 11A and 11B, each of the bottom electrodes BE may be formed in a corresponding one of the electrode holes EC. Each of the bottom electrodes BE may include a conductive pillar BCP, a first conductive pattern CP1, and a second conductive pattern CP2. Forming the bottom electrodes BE may include forming the second conductive pattern CP2 in the electrode holes EC, forming the first conductive pattern CP1 on the second conductive pattern CP2, and forming the conductive pillar BCP on the first conductive pattern CP1.

The second conductive pattern CP2 may be formed to cover inner walls of the electrode holes EC with a uniform thickness. The first conductive pattern CP1 may be formed on the second conductive pattern CP2, and cover the second conductive pattern CP2 with a uniform thickness. The second conductive pattern CP2 may function as a seed layer for forming the first conductive pattern CP1. Accordingly, the first conductive pattern CP1 of high quality may be formed. For example, the second conductive pattern CP2 may include TiN (titanium nitride), and the first conductive pattern CP1 may include NbN (niobium nitride).

Forming the first conductive pattern CP1 may include doping an impurity in the first conductive pattern CP1. The impurity may be doped by in-situ method in the first conductive pattern CP1 while the first conductive pattern CP1 is formed. Alternatively, after the first conductive pattern CP1 is formed, the impurity may be doped in the first conductive pattern CP1. The impurity may prevent a lattice dislocation of elements constituting the first conductive pattern CP1 to improve the physical hardness of the first conductive pattern CP1. For example, the impurity may include at least one of niobium, silicon, tantalum, and vanadium.

Forming the conductive pillar BCP may include doping an impurity in the conductive column BCP. Similar to the first conductive pattern CP1, the impurity may be doped by in-situ method or ex-situ method in the conductive pillar BCP. The impurity may improve the physical hardness of the conductive pillar BCP. For example, the impurity may include at least one of niobium, silicon, tantalum, and vanadium.

According to embodiments of the inventive concept, by doping impurity into the first conductive pattern CP1 and/or the conductive pillar BCP, the physical hardness of the first conductive pattern CPU1 and/or conductive pillar BCP may be improved. For this reason, warpage of the bottom electrodes BE in the process of forming the dielectric layer CIL and the top electrode TE may be prevented or suppressed.

Forming the conductive pillar BCP may further include performing a planarization process on the conductive pillar BCP. An upper surface of the third mold layer 525 may be exposed again due to the planarization process. Thus, a plurality of bottom electrodes BE spaced apart from each other may be formed.

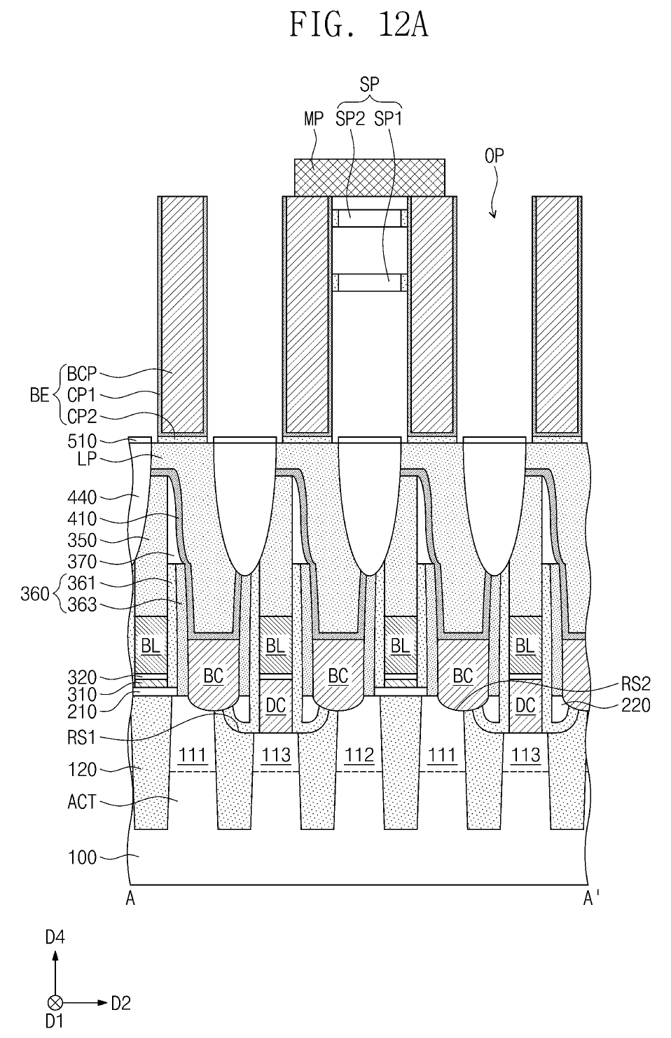

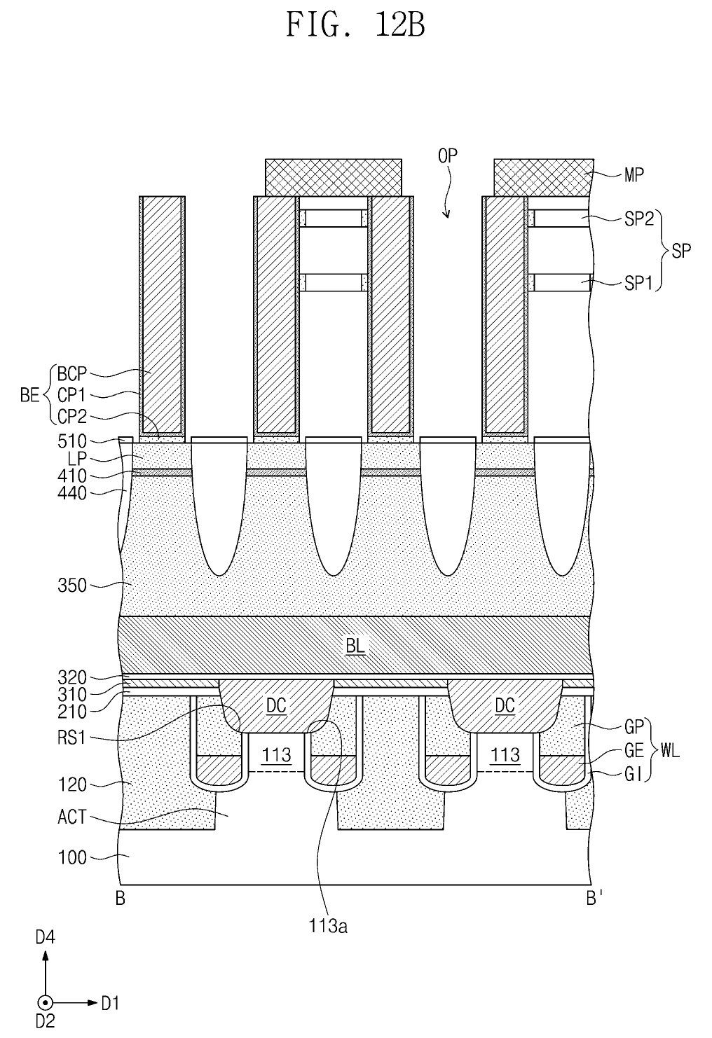

Referring to FIGS. 12A and 12B, a mask pattern MP may be formed on the third mold layer 525, and an etching process using the mask pattern MP may be performed. The etching process may remove the first to third mold layers 521, 523, and 525 and the first and second support patterns SP1 and SP2 exposed by the mask pattern MP. The etching process may not remove the bottom electrodes BE. As a result, openings OP exposing sidewalls of the bottom electrodes BE may be formed.

Through the openings OP, the first to third mold layers 521, 523, and 525 may be completely removed. Since the first and second support patterns SP1 and SP2 may include a material having an etch selectivity with respect to the first to third mold layers 521, 523, and 525, the first and second supporting patterns SP1 and SP2 may remain without being removed. In the process of removing the first to third mold layers 521, 523, and 525, the second conductive pattern CP2 of the bottom electrode BE may protect the first conductive pattern CP1. Therefore, the first conductive pattern CP1 may be prevented from being removed by the process of removing the first to third mold layers 521, 523, and 525.

Thereafter, a wet etching process of selectively removing the second conductive pattern CP2 may be performed. The second conductive pattern CP2 exposed through the openings OP may be removed. In a region where the area exposed to the outside is small, the second conductive pattern CP2 may partially remain. For example, the second conductive pattern CP2 may remain between the first conductive pattern CP1 and the landing pads LP and between the first and second support patterns SP1 and SP2 and the first conductive pattern CP1. Due to the wet etching process, the second conductive pattern CP2 may have recessed side surfaces RSS and recessed upper and lower surfaces RUS and RLS as described with reference to FIG. 4.

Referring again to FIGS. 3A, 3B, and 4, after the mask pattern MP may be removed, a dielectric layer CIL and a top electrode TE may be sequentially formed on the bottom electrodes BE. The dielectric layer CIL may cover the bottom electrodes BE and the support patterns SP with a uniform thickness. The dielectric layer CIL may be formed on the first conductive pattern CP1 of the bottom electrodes BE. Since the first conductive pattern CP1 may have a lattice constant substantially similar to that of the dielectric layer CIL, the dielectric layer CIL having excellent crystallinity may be formed. Accordingly, electrical characteristics of the semiconductor memory device may be improved.

The bottom electrode of the semiconductor memory device may include the conductive pillar and the conductive pattern surrounding the conductive pillar. The impurity doped in at least one of the conductive pillar and the conductive pattern may prevent lattice dislocations from being generated in the conductive pillar and the conductive pattern. As a result, the physical hardness of the bottom electrode may be improved. By improving the physical hardness of the bottom electrode having a large aspect ratio, warpage of the bottom electrode may be prevented. The bottom electrodes adjacent to each other may be prevented from being physically in contact with or electrically connected to each other. Accordingly, electrical characteristics and durability of the semiconductor memory device may be improved.

While embodiments are described above, it will be appreciated by those skilled in the art that various modifications, alterations, and substitutions may be made without departing from the spirit and scope of the inventive concept. Accordingly, the example embodiments of the inventive concept should be interpreted as illustrative and not limiting.

What is claimed is:

1. A semiconductor memory device comprising:
a cell transistor provided with a substrate;
a first capacitor electrode on the substrate, the first capacitor electrode being electrically connected to the cell transistor;
a second capacitor electrode on the first capacitor electrode; and
a capacitor dielectric layer between the first capacitor electrode and the second capacitor electrode,
wherein the first capacitor electrode comprises a conductive pillar and a first conductive pattern surrounding the conductive pillar,
wherein the first conductive pattern comprises a first material including a first element and doped with a second element, the first element being different from the second element,
wherein the conductive pillar comprises a second material including the first element and doped with the second element, and
wherein the first material and the second material are different from each other.

2. The semiconductor memory device of claim 1, wherein the first material has a greater atomic percentage of the first element than the second material.

3. The semiconductor memory device of claim 2, wherein the first material has a greater atomic percentage of the second element than the second material.

4. The semiconductor memory device of claim 3,
wherein the second element is silicon, and
wherein the first element is niobium.

5. The semiconductor memory device of claim 1,
wherein the first conductive pattern has a shape of cylinder, and
wherein the conductive pillar extends in a direction perpendicular to an upper surface of the substrate inside the first conductive pattern.

6. The semiconductor memory device of claim 1,
wherein the first capacitor electrode comprises a second conductive pattern in contact with the first conductive pattern, and
wherein a thickness of the second conductive pattern is greater than that of the first conductive pattern.

7. The semiconductor memory device of claim 6, further comprising:
a support pattern on a side surface of the first conductive pattern,
wherein the second conductive pattern is between the support pattern and the first conductive pattern.

8. The semiconductor memory device of claim 7, wherein the capacitor dielectric layer extends on an upper surface and a lower surface of the support pattern, and is in contact with the second conductive pattern.

9. The semiconductor memory device of claim 7, wherein the support pattern comprises a plurality of subsidiary support patterns that are vertically spaced apart from each other.

10. The semiconductor memory device of claim 6, wherein the second conductive pattern is disposed between the first conductive pattern and the cell transistor, and
wherein the second conductive pattern has a side surface recessed therein.

11. A semiconductor memory device comprising:
a word line on a substrate and crossing an active pattern;
a bit line crossing the word line and on the word line;
a landing pad spaced apart from the word line and the bit line; and
a data storage pattern connected with the landing pad,
wherein the data storage pattern comprises a bottom electrode, a top electrode, and a dielectric layer therebetween,
wherein the bottom electrode comprises:
a conductive pillar extending in a direction perpendicular to an upper surface of the substrate;
a first conductive pattern surrounding the conductive pillar; and
a second conductive pattern between the first conductive pattern and the landing pad, and
wherein the dielectric layer is in contact with the first conductive pattern.

12. The semiconductor memory device of claim 11, wherein the dielectric layer comprises:
a first portion covering a side surface of the first conductive pattern and having a uniform thickness; and
a second portion extending on a recessed side surface of the second conductive pattern.

13. The semiconductor memory device of claim 11, wherein a thickness of the first conductive pattern is smaller than that of the second conductive pattern.

14. The semiconductor memory device of claim 11, wherein at least one of the conductive pillar and the first conductive pattern is doped with an impurity that is not a charge carrier impurity.

15. The semiconductor memory device of claim 14, wherein the impurity comprises one of niobium, silicon, tantalum, and vanadium.

16. A semiconductor memory device comprising:
a device isolation pattern defining an active pattern in a substrate;
a pair of word lines crossing the active pattern;
a bit line electrically connected to a central portion of the active pattern, wherein the central portion is disposed between the pair of word lines;
landing pads each connected with edge portions of the active pattern spaced apart from the central portion;
bottom capacitor electrodes, each bottom capacitor electrode being electrically connected to a corresponding one of the landing pads;
a support pattern between the bottom capacitor electrodes and connecting the bottom capacitor electrodes;
a top capacitor electrode covering the bottom capacitor electrodes and the support pattern; and
a capacitor dielectric layer between the bottom capacitor electrode and the top capacitor electrode,
wherein the bottom capacitor electrode comprises a conductive pillar and a first conductive pattern surrounding the conductive pillar,
wherein the first conductive pattern comprises a first material including a first element and doped with a second element,
wherein the conductive pillar comprises a second material including the first element and doped with the second element,
wherein the first element is different from the second element, and
wherein the first material and the second material have different atomic percentage ratios of the first element to the second element.

17. The semiconductor memory device of claim 16, wherein the first material has a greater atomic percentage of the first element than the second material, and
wherein the first material has a greater atomic percentage of the second element than the second material.

18. The semiconductor memory device of claim 16, wherein each of the bottom capacitor electrodes comprises a second conductive pattern, and
wherein the second conductive pattern is disposed between the support pattern and the first conductive pattern and between the landing pads and the first conductive pattern, and
wherein the second conductive pattern is in contact with a side surface of the first conductive pattern.

19. The semiconductor memory device of claim 18, wherein the capacitor dielectric layer is in contact with the side surface of the first conductive pattern.

20. The semiconductor memory device of claim 18, wherein the first material comprises TiSiN,
wherein the second material comprises NbN, and
wherein the second conductive pattern comprises TiN.
